(19) United States
(12) Patent Application Publication
(10) Pub. No.: US 2020/0304137 A1
(43) Pub. Date: Sep. 24, 2020

(54) AD CONVERSION CIRCUIT

(71) Applicants: Kabushiki Kaisha Toshiba, Tokyo (JP); Toshiba Electronic Devices & Storage Corporation, Tokyo (JP)

(72) Inventors: Shigeyasu Iwata, Hamura Tokyo (JP); Tsuneo Suzuki, Kamakura Kanagawa (JP)

(21) Appl. No.: 16/557,069

(22) Filed: Aug. 30, 2019

(30) Foreign Application Priority Data
Mar. 18, 2019 (JP) 2019-050360

(51) Int. Cl. H03M 3/00

(52) U.S. Cl. CPC H03M 3/368; H03M 3/424; H03M 3/458

(57) ABSTRACT

According to one embodiment, in an AD conversion circuit, a first delta-sigma conversion circuit includes a first quantizer having 1.5-bit resolution, a first signal line electrically connected to an input side of the first quantizer, and a first feedback line returning from an output side of the first quantizer to a side of an input node of the first signal line. A second delta-sigma conversion circuit includes a second quantizer having multi-bit resolution, a second signal line electrically connected to an input side of the second quantizer, and a second feedback line returning from an output side of the second quantizer to a side of an input node of the second signal line, an intermediate node of the first signal line and as intermediate node of the first feedback line being electrically connected to the input node of the second signal line.

### CROSS-REFERENCE TO RELATED APPLICATIONS

This application is based upon and claims the benefit of priority from Japanese Patent Application No. 2019-050360, filed on Mar. 18, 2019; the entire contents of which are incorporated herein by reference.

### FIELD

Embodiments described herein relate generally to an analog-digital (AD) conversion circuit.

### BACKGROUND

An AD conversion circuit quantizes an analog signal and outputs a signal in accordance with a result of the quantization. At this time, an error included in the signal is desirably reduced.

### BRIEF DESCRIPTION OF THE DRAWINGS

FIG. 1 is a block diagram illustrating a configuration of an AD conversion circuit according to one embodiment.

FIG. 2 illustrates a linearity model of an AD conversion unit according to the embodiment.

FIG. 3 illustrates a circuit configuration of the AD conversion unit according to the embodiment.

FIGS. 4A and 4B illustrate operation of a quantizer according to the embodiment.

FIG. 5 is a waveform view illustrating operation of an adjustment circuit according to the embodiment.

FIG. 6 is a circuit diagram illustrating a configuration of an integration circuit according to the embodiment.

FIG. 7 illustrates operation of the integration circuit according to the embodiment.

### DETAILED DESCRIPTION

In general, according to one embodiment, there is an AD conversion circuit including a first delta-sigma conversion circuit and a second delta-sigma conversion circuit. The first delta-sigma conversion circuit includes a first quantizer having 1.5-bit resolution, a first signal line electrically connected to an input side of the first quantizer, and a first feedback line returning from an output side of the first quantizer to a side of an input node of the first signal line. The second delta-sigma conversion circuit includes a second quantizer having multi-bit resolution, a second signal line electrically connected to an input side of the second quantizer, and a second feedback line returning from an output side of the second quantizer to a side of an input node of the second signal line, an intermediate node of the first signal line and an intermediate node of the first feedback line being electrically connected to the input node of the second signal line.

Exemplary embodiments of an AD conversion circuit will be explained below in detail with reference to the accompanying drawings. The present invention is not limited to the following embodiments.

### EMBODIMENTS

An AD conversion circuit according to one embodiment quantizes an analog signal and outputs a digital signal in accordance with a result of the quantization. The AD conversion circuit can be configured as a delta-sigma AD conversion circuit. The delta-sigma AD conversion circuit derives a difference (Δ) between a signal obtained by integrating (Σ) an analog signal and a signal obtained by performing DA conversion or the like on a digital signal and feeding back the signal, makes a comparison with reference voltage, and performs quantization. In the AD conversion circuit, at the time of quantizing the analog signal, a quantization error is generated in accordance with a level of the analog signal and a level of the quantization bit rate. For the quantization error, as the number of orders, that is, the number of stages of feedback, of the AD conversion circuit increases, an effect of a noise shaping characteristic, in which a peak of the frequency characteristic is shifted to a high frequency side, can be raised.

However, in the AD conversion circuit, in a case in which the number of stages of feedback is increased, operation of the AD conversion circuit may be unstable. For this reason, the AD conversion circuit can be configured as a third-order multi-stage noise shaping (MASH) delta-sigma AD conversion circuit. In the a third-order MASH delta-sigma AD conversion circuit, by connecting a second-order delta-sigma conversion circuit to a first-order delta-sigma conversion circuit in a cascaded manner and reducing (for example, cancelling) an error between the circuits, a third-order noise shaping characteristic can be achieved with stability equivalent to second-order stability.

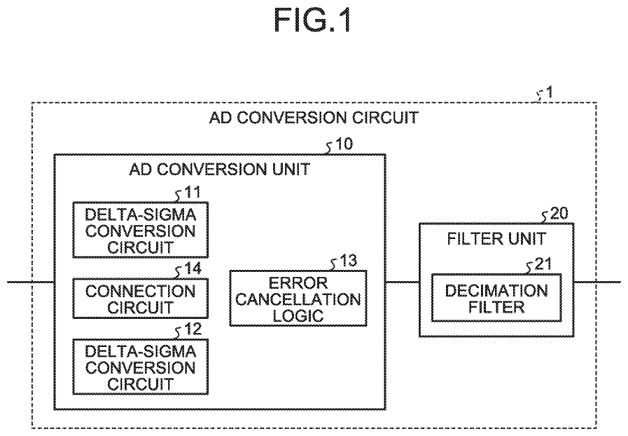

For example, an AD conversion circuit 1 can be configured as illustrated in FIG. 1. The AD conversion circuit 1 includes an AD conversion unit 10 and a filter unit 20. The AD conversion unit 10 includes a delta-sigma conversion circuit 11, a delta-sigma conversion circuit 12, a connection circuit 14, and an error reduction circuit (error cancellation logic) 13. The filter unit 20 includes a decimation filter 21. The delta-sigma conversion circuit 11 can be configured as a second-order delta-sigma conversion circuit. The delta-sigma conversion circuit 12 can be configured as a first-order delta-sigma conversion circuit. The connection circuit 14 connects the delta-sigma conversion circuit 12 to the delta-sigma conversion circuit 11 in a cascaded manner. To the error reduction circuit 13, an output node of the delta-sigma conversion circuit 11 and an output node of the delta-sigma conversion circuit 12 are electrically connected. The error reduction circuit 13 cancels a quantization error of the delta-sigma conversion circuit 11 and performs third-order noise shaping on a quantization error of the delta-sigma conversion circuit 12. The noise shaping is processing of shifting a quantization error to a high frequency side. The error reduction circuit 13 is electrically connected between the delta-sigma conversion circuit 11 and delta-sigma conversion circuit 12, and the decimation filter 21. In a case in which the noise shaping is performed appropriately in the error reduction circuit 13, the decimation filter 21 can effectively reduce the quantization error on the high frequency side, and a characteristic (signal-to-noise and distortion ratio (SNDR)) of the AD conversion circuit 1 can be improved.

For example, in the AD conversion circuit 1, in a case in which a 1-bit quantizer is used for the first-stage second-order delta-sigma conversion circuit (that is, the delta-sigma conversion circuit 11) that influences non-linearity of the AD conversion most, linearity can be secured, and in a case in which a multi-bit quantizer is used for the second-stage first-order delta-sigma conversion circuit (that is, the delta-sigma conversion circuit 12), a dynamic range can be secured. Due to the noise shaping, a non-linearity error generated in the quantizer serving as the first-order delta-sigma conversion circuit (that is, the delta-sigma conversion circuit 12) less influences the characteristic (for example, the SNDR) of the AD conversion circuit 1.

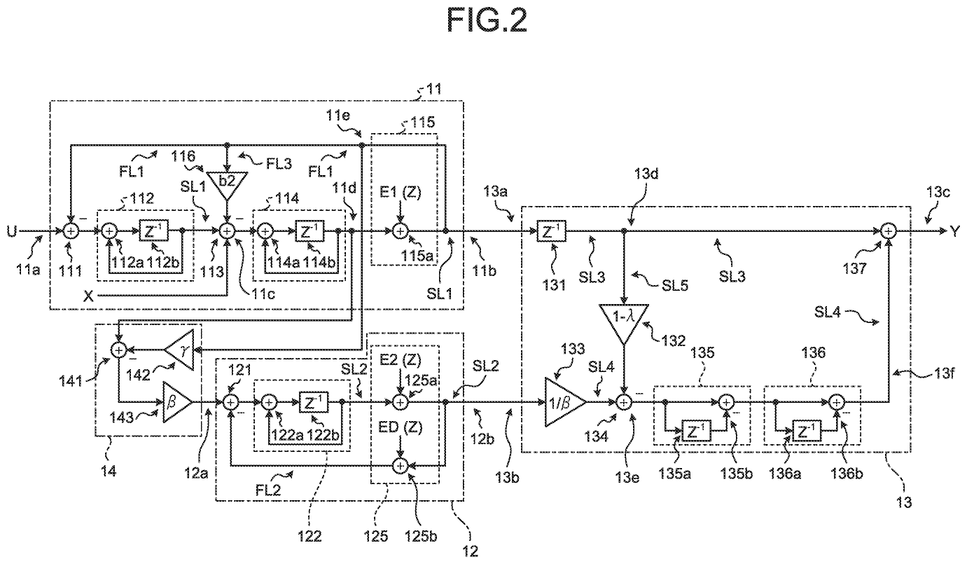

For example, a linearty model of the AD conversion unit 10 is illustrated in FIG. 2. FIG. 2 illustrates the linearity model of the AD conversion unit 10.

As illustrated in FIG. 2, the delta-sigma conversion circuit 11 is configured as a second-order delta-sigma conversion circuit in which two-stage feedback is performed. The delta-sigma conversion circuit 11 includes a signal line SL1, a feedback line FL1, a feedback line FL3, a subtractor 111, an integration circuit 112, a subtractor 113, an integration circuit 114, a quantizer 115, and a coefficient 116.

The signal line SL1 and the feedback line FL1 are electrically connected to be parallel to each other between an input node 11a and an output node 11b. The feedback line FL3 branches off from the feedback line FL1 and is electrically connected to an intermediate node 11c. The intermediate node 11c is a node on the signal line SL1 between the input node 11a and the output node 11b.

On a signal path on the signal line SL1 from the input node 11a to the output node 11b, the subtractor 111, the integration circuit 112, the subtractor 113, the integration circuit 114, and the quantizer 115 are arranged. in order. The integration circuit 112 includes an adder 112a and a delay circuit 112b. An output side of the delay circuit 112b is connected to an input side of the adder 112a. The integration circuit 114 includes an adder 114a and a delay circuit 114b. An output side of the delay circuit 114b is connected to an input side of the adder 114a. The quantizer 115 includes an adder 115a.

The quantizer 115 is arranged between the feedback line FL1 and the output node 11b. On a feedback path from the feedback line FL1 and the feedback line FL3 back to the intermediate node 11c, the coefficient 116 is arranged.

The delta-sigma conversion circuit 12 is configured as a first-order delta-sigma conversion circuit in which one-stage feedback is performed. The delta-sigma conversion circuit 12 includes a signal line SL2, a feedback line FL2, a subtractor 121, an integration circuit 122, and a quantizer 125.

The signal line SL2 and the feedback line FL2 are electrically connected to be parallel to each other between an input node 12a and an output node 12b.

On a signal path on the signal line SL2 from the input node 12a to the output node 12b, the subtractor 121, the integration circuit 122, and the quantizer 125 are arranged in order. The quantizer 125 is arranged between the feedback line FL2 and the output node 12b. The integration circuit 122 includes an adder 122a and a delay circuit 122b. The quantizer 125 includes an adder 125a and an adder 125b.

The connection circuit 14 electrically connects the input node 12a of the signal line SL2 to an intermediate node 11d of the signal line SL1 and an intermediate node 11e of the feedback line FL1. The connection circuit 14 includes an adder 141, a coefficient 142, and a coefficient 143. An input side of the adder 141 is electrically connected to the intermediate node 11d of the signal line SL1 and an output node of the coefficient 142, and an output side thereof is electrically connected to an input node of the coefficient 143. An input side of the coefficient 142 is electrically connected to the intermediate node 11e of the feedback line FL1, and an output side thereof is electrically connected to an input side of the adder 141. An input side of the coefficient 143 is electrically connected to the output side of the adder 141 and an output side thereof is electrically connected to the signal line SL2.

The error reduction circuit 13 reduces an error of the second-order delta-sigma conversion circuit and an error of the first-order delta-sigma conversion circuit. The error reduction circuit 13 includes a signal line SL3, a signal line SL4, a signal line SL5, a delay circuit 131, a coefficient 132, a coefficient 133, a differential circuit 135, a differential circuit 136, and a subtractor 137.

The signal line SL3 and the signal line SL4 are electrically connected to be parallel to each other between input nodes 13a and 13b, and an output node 13c. The signal line SL5 is electrically connected between an intermediate node 13d on the signal line SL3 and an intermediate node 13e on the signal line SL4.

On a signal path on the signal line SL3 from the input node 13a to the output node 13c, the delay circuit 131 and the subtractor 137 are arranged in order. On a signal path on the signal line SL4 from the input node 13b to the output node 13c, the coefficient 133, a subtractor 134, the differential circuit 135, the differential circuit 136, and the subtractor 137 are arranged in order. On a signal path on the signal line SL5 from the intermediate node 13d to the intermediate node 13e, the coefficient 132 is arranged. The differential circuit 135 includes a delay circuit 135a and a subtractor 135b. The differential circuit 136 includes a delay circuit 136a and a subtractor 136b.

Consider the configuration illustrated in FIG. 2 as a z-transformed system. In the delta-sigma conversion circuit 11, in a case in which an analog signal to be input is U(z), the analog signal is equivalently delayed by z⁻¹ in each of the integration circuit 112 and integration circuit 114 and becomes z⁻²·U(z). Also, the quantizer 115 generates a quantized signal (digital signal) from the analog signal. At this time, in the quantizer 115, the adder 115a equivalently adds a quantization error E1(z) to the analog signal and generates the signal (digital signal). The quantization error E1(z) is subtracted from the analog signal in the subtractor 111 when the signal is fed back via the feedback line FL1 and is subtracted from the analog signal in the subtractor 113 when the signal is fed back via the feedback line FL1 and the feedback line FL3. The analog signal obtained by subtracting the quantization error E1(z) in the subtractors 111 and 113 is delayed by z⁻¹ in each of the integration circuit 112 and integration circuit 114 and becomes (1−z⁻²)·E1(z). In a case in which a signal output from the delta-sigma conversion circuit 11 is Y1(z), Y1(z) can be expressed by Equation 1 illustrated below.

Y1(z)=z⁻²·U(z)+(1−z⁻¹)²·E1(z) (1)

Meanwhile, the coefficient 116 includes a coefficient b2 and multiplies the signal fed back via the feedback line FL1 and the feedback line FL3 by the coefficient b2.

In the connection circuit 14, the coefficient 142 multiplies the signal (analog signal) fed back via the feedback line FL1 by a coefficient λ. The subtractor 141 subtracts the signal amplified in the coefficient 142 from the signal (analog signal) of the intermediate node 11d in the signal line SL1 and supplies the subtracted signal to the coefficient 143. The coefficient 143 multiplies the supplied signal by a coefficient β and inputs the signal to the delta-sigma conversion circuit 12.

The signal (analog signal) input in the delta-sigma conversion circuit 12 is expressed as β·[(1−λ)·Y1(z)−E1(z)], is delayed by z⁻¹ in the integration circuit 122, and becomes z⁻¹·β·[(1−λ)·Y1(z)−E1(z)]. Also, the quantizer 125 generates a quantized signal (digital signal) from the analog signal. At this time, in the quantizer 125, the adder 125a equivalently adds a quantization error E2(z) to the analog signal and generates the signal (digital signal). The quantization error E1(z) is subtracted from the analog signal in the subtractor 121 when the signal is fed back via the feedback line EL2, and the signal is delayed by z⁻¹ in the integration circuit 122 and becomes (1−z⁻¹)·E2(z). Further, the quantizer 125 DA-converts the signal (digital signal) to generate an analog signal for feedback. At this time, in the quantizer 125, the adder 125a equivalently adds a non-linearity error ED(z) to the digital signal and generates the signal (analog signal). The non-linearity error ED(z) is subtracted from the analog signal in the subtractor 121 when the signal is fed back via the feedback line FL2, and the signal is delayed by z⁻¹ in the integration circuit 122 and becomes −z⁻¹·ED(z). In a case in which a signal output from the delta-sigma conversion circuit 12 is Y1(z), Y1(z) can be expressed by Equation 2 illustrated below.

Y2(z)=z⁻¹·β·[(1−λ) Y1(z)−E1(z)]+(1−z⁻¹)·E2(z)−z⁻¹·ED(z) (2)

In the error reduction circuit 13, the signal (digital signal) Y1(z) supplied into the input node 13a is delayed by z⁻¹ in the delay circuit 131 and becomes z⁻¹·Y1(z). The signal z⁻¹·Y1(z) is supplied to the subtractor 137 and the coefficient 132, respectively. The signal z⁻¹·Y1(z) is multiplied by a coefficient (1−λ) in the coefficient 132 and becomes (1−λ)·Y1(z). The signal (digital signal) Y2(z) supplied into the input node 13b is multiplied by a coefficient (1/β) in the coefficient 133 and becomes (1/β)·Y2(z). This signal becomes (1/β)·Y2(z)−(1−λ)·Y1(z) in the subtractor 134 and becomes (1−z⁻¹)²·[(1/β)·Y2(z)−(1−λ)·Y1(z)] by taking difference between the signal and a component delayed by z⁻¹ in each of the differential circuits 135 and 136. This signal can be expressed by Equation 3 illustrated below by substituting Equation 1 and Equation 2 in the signal.

z⁻¹·(1−z⁻¹)⁻²·E1(z)+(1/β)·[(1−z⁻¹)⁻³·E2(z)−z⁻¹·(1−z⁻¹)⁻²·ED(z)] (3)

The subtractor 137 subtracts the signal (1−z⁻¹)²·[(1/β)−Y2(z)−(1−λ)·Y1(z)] from the signal z⁻¹·Y1(z) to generate a signal z⁻¹·Y1(z)−(1−z⁻¹)²·[(1/β)·Y2(z)−(1−λ)·Y1(z)]. An acquired signal can be expressed by Equation 4 illustrated below.

z⁻³·U(z)+(1/β)·[(1−z⁻¹)⁻³·E2(z)−z⁻¹·(1−z⁻¹)⁻²·ED(z)] (4)

As illustrated in Equation 4, third-order noise shaping expressed as (1−z⁻¹)³ is performed on the quantization error E2(z) that can be generated in the quantizer of the first-order delta-sigma conversion circuit (delta-sigma conversion circuit 12). Second-order noise shaping expressed as (1−z⁻¹)² is performed on the non-linearity error ED(z) that can be generated in the quantizer (multi-bit digital-analog converter (DAC)) of the first-order delta-sigma conversion circuit (delta-sigma conversion circuit 12). Conversely, no noise shaping is performed on the input U(z) of the second-order delta-sigma conversion circuit (delta-sigma conversion circuit 11).

For example, in a case of λ=β1 for the purpose of obtaining a characteristic (SNDR) at the time of input of a small signal, an input in the first-order delta-sigma conversion circuit (delta-sigma conversion circuit 12) is equal to the quantization error E1(z) of the second-order delta-sigma conversion circuit (delta-sigma conversion circuit 11). The quantization error E1(z) increases as the input signal U(z) increases. At the time of input of a large signal, when an input in the first-order delta-sigma conversion circuit (delta-sigma conversion circuit 12) is in an overloaded state, the SNDR will drastically be degraded.

To obtain the characteristic (SNDR) at the time of input of the large signal, the coefficients λ and β are adjusted to prevent the overloaded state. Normally, β is set to be lower than 1, and as illustrated in FIG. 2, the quantization error E2(z) and the non-linearity error ED(z) of the DAC in the output Y2(z) of the first-order delta-sigma conversion circuit (delta-sigma conversion circuit 12) respectively increase at a rate of 1/β. Consequently, at the time of input of the small signal, the characteristic (SNDR) will drastically be degraded.

In other words, the characteristics (SNDR) at the time of input of the large signal and at the time of input of the small signal are in trade-off relation. At the time of input of the large signal and at the time of input of the small signal, the characteristic (SNDR) of the AD conversion circuit 1 is desirably improved, and the dynamic range is desirably expanded.

For example, in a case in which the quantization bit rate can be raised, it is expected that the quantization error E1(z) can be reduced, and that the dynamic range of the AD conversion circuit 1 can be expanded. One way to raise the bit rate is to use a multi-bit quantizer for the quantizer of the second-order delta-sigma conversion circuit (delta-sigma conversion circuit 11). In this case, a non-linearity error may be generated in the quantizer of the second-order delta-sigma conversion circuit. The non-linearity error will directly be fed back to the input signal and be included in the input signal U(z). As illustrated in Equation 4, noise shaping is not performed on the input signal U(z) including the non-linearity error. There is a method for reducing the error such as mismatch error shaping. However, using this method will complicate the circuit configuration.

Under such circumstances, in the present embodiment, in the AD conversion circuit 1, a quantizer having 1.5-bit resolution is used for the quantizer in the second-order delta-sigma conversion circuit (delta-sigma conversion circuit 11) to achieve raising of the quantization bit rate and reduction of the non-linearity error.

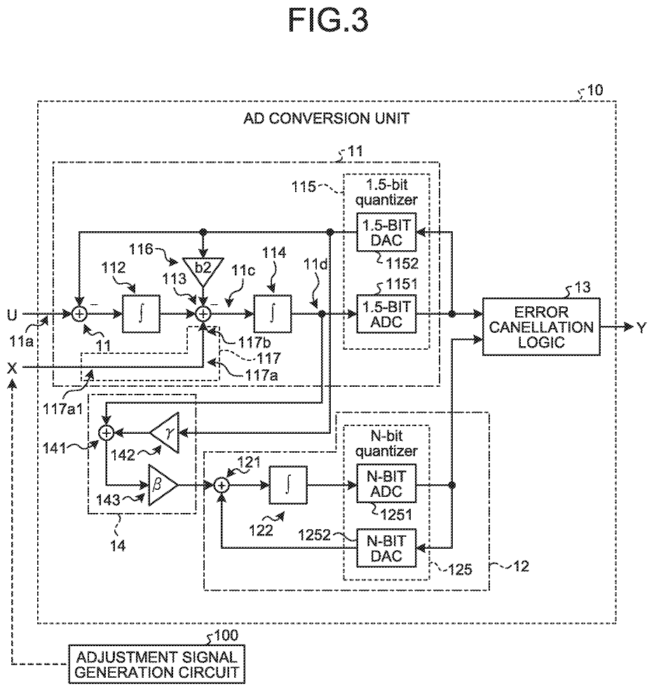

Specifically, the AD conversion circuit 1 can be configured as illustrated in FIG. 3. In the delta-sigma conversion circuit 11, the quantizer 115 is configured as a 1.5-bit quantizer having 1.5-bit resolution. The quantizer 115 includes a 1.5-bit analog-digital converter (AD converter (ADC)) 1151 and a 1.5-bit digital-analog converter (DA converter (DAC)) 1152.

In the delta-sigma conversion circuit 12, the quantizer 125 is configured as an N-bit quantizer having N-bit (N is an integer of at least two) resolution. The quantizer 125 includes an N-bit ADC 1251 and an N-bit DAC 1252.

In the delta-sigma conversion circuit 11, the 1.5-bit ADC 1151 AD-converts an analog signal with resolution of 1.5 bits and generates a digital signal having a quantized bit value. The 1.5-bit DAC 1152 DA-converts the digital signal with resolution of 1.5 bits and generates an analog signal.

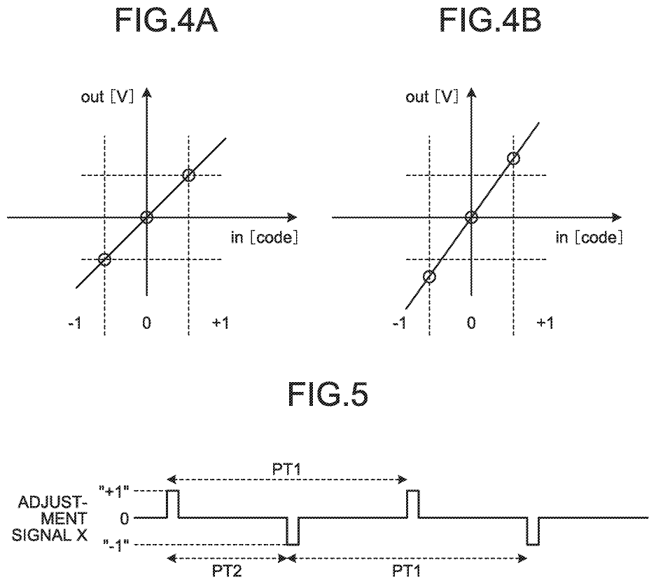

In the quantizer 115, the 1.5-bit DAC 1152 has input/output transmission characteristics as illustrated in FIGS. 4A and 4B. In each of FIGS. 4A and 4B, the horizontal axis represents an input digital signal (in) while the vertical axis represents an output analog signal (out). FIGS. 4A and 4B illustrate operation of the quantizer 115. That is, FIG. 4A illustrates an input/output transmission characteristic of the 1.5-bit DAC 1152 in a case in which a quantized signal (digital signal) does not include an error. FIG. 4B illustrates an input/output transmission characteristic of the 1.5-hit DAC 1152 in a case in which a quantized signal (digital signal) includes an error. In the DA conversion by means of the 1.5-bit DAC 1152, linearity in the DA conversion can be maintained not only in a case in which the signal does not include an error as illustrated in FIG. 4A but also in a case in which the signal includes an error as illustrated in FIG. 4B. Accordingly, the quantization error E1(z) in the 1.5-bit ADC 1151 can be low, and the non-linearity error in the 1.5-bit DAC 1152 can he restricted from being generated.

However, in a case in which the 1.5-bit quantizer is used for the quantizer 115, the digital signal (code value) to be input into the 1.5-bit DAC 1152 may successively be “0” when the amplitude of the analog signal U to be input into the AD conversion circuit 1 is low, a significant difference between the input signal value and the threshold value may not be fed hack, and no noise shaping may thus be performed.

To solve the problem, the delta-sigma conversion circuit 11 illustrated in FIG. 3 further includes an adjustment circuit 117. An input side of the adjustment circuit 117 is electrically connected to an external adjustment signal generation circuit 100, and an output side thereof is electrically connected to the subtractor 113. The adjustment circuit 117 includes a line 117a. Note that the adjustment signal generation circuit 100 may be provided in the adjustment circuit 117.

The tine 117a receives at a first end 117a1 an adjustment signal X generated in the adjustment signal generation circuit 100 and supplies the adjustment signal X via a second end 117a3 to the subtractor 113. The subtractor 113 adds the adjustment signal X to a result obtained by subtracting the feedback signal from the analog signal and supplies the signal to the integration circuit 114.

The adjustment signal X may be a signal including pulses in which the amplitude “+1” and the amplitude “−1” come cyclically, as illustrated in FIG. 5, for example. FIG. 5 is a waveform view illustrating operation of the adjustment circuit 117. The cycle of the pulse amplitude “+1” in the signal X may be a cycle PT1 corresponding to a predetermined frequency that is higher than the signal band. Similarly, the cycle of the pulse amplitude “−1” in the signal X may be the cycle PT1 corresponding to a predetermined frequency that is higher than the signal band. A time interval PT2 between the pulse amplitude “+1” and the pulse amplitude “−1” in the signal X may have a time length at a predetermined ratio to the cycle PT1 and can be approximately a half of the cycle PT1, for example.

For example, in the AD conversion circuit 1 in FIG. 5, in a case in which the sampling rate is 32 MSPS, in which the oversampling rate is 32 times, and in which the signal band is 500 kHz, cycle PT1=1 MHz may be established.

Accordingly, when the amplitude of the input analog signal is low, the digital signal (code value) to be input into the 1.5-bit GAG 1152 can be prevented from successively being “0”, a difference between the input signal value and the threshold value can be fed back, and noise shaping can be performed. Since the 1-MHz component of the input X is higher than 500 kHz, which is the band of the input signal U, the 1-MHz component can be eliminated in the subsequent decimation filter 21 together with the noise-shaped quantization error.

Note that, although the adjustment signal X is input into the node 11c between the first-stage integration circuit 112 and the second-stage integration circuit 114 in FIG. 3, the adjustment signal X may be input into the node 11d between the second-stage integration circuit 114 and the 1.5-bit ADC 1511. Also, the input side (input node 11a) of the first-stage integration circuit 112 is not appropriate as a portion into which the adjustment signal X is input since the input side has a strict requirement about noise.

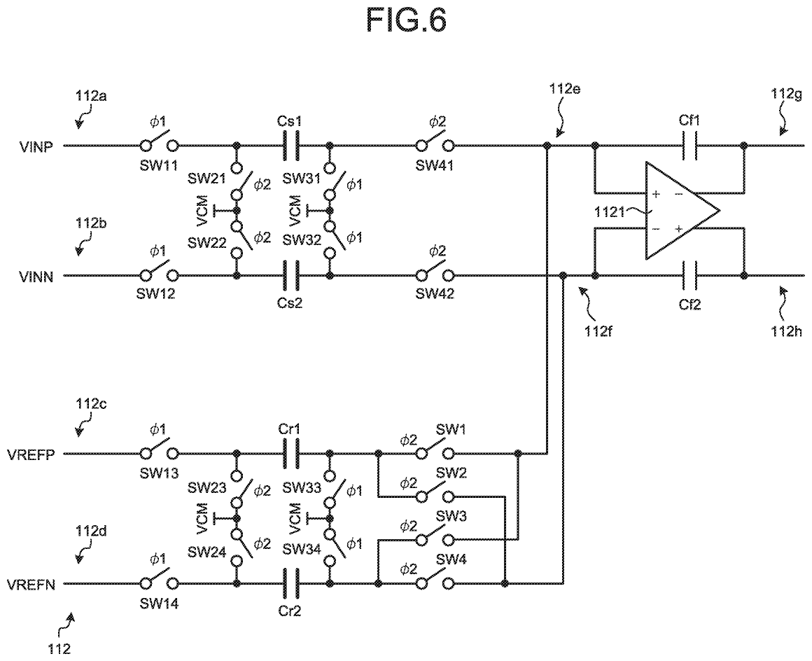

In a case in which the AD conversion circuit 1 is configured as a third-order MASH delta-sigma AD conversion circuit, each of the integration circuits 112, 114, and 122 is configured with use of a switched capacitor in many cases. For example, the integration circuit 112 can be configured as illustrated in FIG. 6. FIG. 6 is a circuit diagram illustrating a configuration of the integration circuit 112 and illustrates a configuration of differential input and differential output. Although FIG. 6 illustrates a configuration of the integration circuit 112, configurations of the other integration circuits 114 and 122 may be similar to that of the integration circuit 112.

The integration circuit 112 includes a plurality of switches SW11, SW12, SW13, SW14, SW21, SW22, SW23, SW24, SW31, SW32, SW33, SW34, SW41, SW42, SW1, SW2, SW3, and SW4, sampling capacitors Cs1, Cs2, Cr1, and Cr2, an amplifier 1121, and feedback capacitors Cf1 and Cf2.

Input voltage VINP is supplied to an input node 112a. Input voltage VINN is supplied to an input node 112b. Reference voltage VREFP is supplied to an input node 112c. Reference voltage VREFN is supplied to an input node 112d.

One end of the switch SW11 is connected to the input node 112a, and the other end thereof is connected to one end of the sampling capacitor Cs1 and one end of the switch SW21. One end of the switch SW12 is connected to the input node 112b, and the other end thereof is connected to one end of the sampling capacitor Cs2 and one end of the switch SW22. The other end of the switch SW21 and the other end of the switch SW22 are connected to common-mode voltage VCM. The other end of the sampling capacitor Cs1 is connected to one end of the switch SW31 and one end of the switch SW41. The other end of the sampling capacitor Cs2 is connected to one end of the switch SW32 and one end of the switch SW42. The other end of the switch SW31 and the other end of the switch SW32 are connected to the common-mode voltage VCM. The other end of the switch SW41 is connected via a node 112e to a non-inverting input terminal (+) of the amplifier 1121 and one end of the feedback capacitor Cf1. The other end of the switch SW42 is connected via a node 112f to an inverting input terminal (−) of the amplifier 1121 and one end of the feedback capacitor Cf2.

One end of the switch SW13 is connected to the input node 112c, and the other end thereof is connected to one end of the sampling capacitor Cr1 and one end of the switch SW23. One end of the switch SW14 is connected to the input node 112d, and the other end thereof is connected to one end of the sampling capacitor Cr2 and one end of the switch SW24. The other end of the switch SW23 and the other end of the switch SW24 are connected to the common-mode voltage VCM. The other end of the sampling capacitor Cr1 is connected to one end of the switch SW33, one end of the switch SW1, and one end of the switch SW2. The other end of the sampling capacitor Cr2 is connected to one end of the switch SW34, one end of the switch SW3, and one end of the switch SW4. The other end of the switch SW33 and the other end of the switch SW34 are connected to the common-mode voltage VCM. The other end of the switch SW1 is connected via the node 112e to the non-inverting input terminal (+) of the amplifier 1121 and one end of the feedback capacitor Cf1. The other end of the switch SW2 is connected via the node 112f to the inverting input terminal (−) of the amplifier 1121 and one end of the feedback capacitor Cf2. The other end of the switch SW3 is connected via the node 112e to the non-inverting input terminal (+) of the amplifier 1121 and one end of the feedback capacitor Cf1. The other end of the switch SW4 is connected via the node 112f to the inverting input terminal (−) of the amplifier 1121 and one end of the feedback capacitor Cf2.

The inverting output terminal (−) of the amplifier 1121 and the other end of the feedback capacitor Cf1 are connected to an output node 112g. The non-inverting output terminal (+) of the amplifier 1121 and the other end of the feedback capacitor Cf2 are connected to an output node 112h.

In the integration circuit 112, kT/C noise caused by the sampling capacitors Cs1, Cs2, Cr1, and Cr2 is a bottleneck for the characteristic in many cases. The input voltage VINP and the reference voltage VREFP are sampled in a φ1 phase and are integrated in a φ2 phase. For example, in the φ1 phase (a period in which a signal φ1 is in an active level), the switches SW11 to SW14 and SW31 to SW34 are selectively kept in on states. In the φ2 phase (a period in which a signal φ2 is in an active level), the switches SW21 to SW24 and SF41 to SW42 are selectively kept in on states.

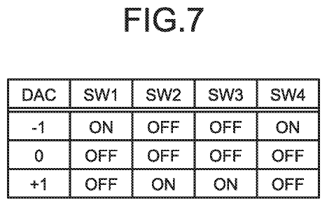

Also, in the φ2 phase, the switches SW1, SW2, SW3, and SW4 are turned on or off in accordance with an input code of the DAC in the quantizer 115 as illustrated in FIG. 7. For example, in a case in which the quantizer 115 is in a 1.5-bit configuration, when the input code of the 1.5-bit DAC 1152 is “−1”, the switches SW1, SW2, SW3, and SW4 are kept in an on state, an off state, an off state, and an on state, respectively. When the input code of the 1.5-bit DAC 1152 “+1”, the switches SW1, SW2, SW3, and SW4 are kept in an off state, an on state, an on state, and an off state, respectively.

On the other hand, when the input code of the 1.5-bit DAC 1152 is “0”, the switches SW1, SW2, SW3, and SW4 are all kept in off states as illustrated in FIG. 7 and do not transfer charges sampled in the φ1 phase. FIG. 7 illustrates operation of the integration circuit 112. Accordingly, the kT/C noise of the switched capacitors is expressed as Equation 5 illustrated below.

$${P}_{n} = \frac{4 kT}{OS \cdot Cs} + ( 1 - Zr ) \cdot \frac{4 kT}{OSR \cdot Cr} {( \frac{Cr}{Cs} )}^{2} \qquad ( 5 )$$

In this equation, OSR is an oversampling rate, and Zr is a rate at which the DAC input code is “0”. In other words, with the 1.5-bit configuration, the higher the rate at which the DAC input code is “0” is, the lower the kT/C noise on the reference voltage side can be.

As described above, in the AD conversion circuit 1, the quantizer in the second-order delta-sigma conversion circuit (delta-sigma conversion circuit 11) is the quantizer having 1.5-bit resolution. Consequently, the trade-off between the large signal characteristic and the small signal characteristic can be solved, and the non-linearity error can be reduced while the quantization bit rate is raised. As a result, the accuracy of the AD conversion can be improved, and the dynamic range of the AD conversion can be expanded.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. An AD conversion circuit comprising:
a first delta-sigma conversion circuit that includes a first quantizer having 1.5-bit resolution, a first signal line electrically connected to an input side of the first quantizer, and a first feedback line returning from an output side of the first quantizer to a side of an input node of the first signal line; and
a second delta-sigma conversion circuit that includes a second quantizer having multi-bit resolution, a second signal line electrically connected to an input side of the second quantizer, and a second feedback line returning from an output side of the second quantizer to a side of an input node of the second signal line, an intermediate node of the first signal line and an intermediate node of the first feedback line being electrically connected to the input node of the second signal line,
wherein the first delta-sigma conversion circuit further includes an adjustment circuit electrically connected to the intermediate node of the first signal line.

2. (canceled)

3. The AD conversion circuit according to claim 1, wherein
the first signal line transmits an input signal, and
the adjustment circuit inputs an adjustment signal that is cyclic into the intermediate node of the first signal line.

4. The AD conversion circuit according to claim 1, wherein
the adjustment circuit includes a line electrically connecting an adjustment signal generation circuit to the intermediate node of the first signal line.

5. The AD conversion circuit according to claim 3, wherein
the adjustment signal has a frequency that is higher than a signal band.

6. The AD conversion circuit according to claim 5, wherein
the adjustment signal includes first pulse amplitude at a first cycle corresponding to the frequency that is higher than the signal band and second pulse amplitude at a second cycle corresponding to the frequency that is higher than the signal band.

7. The AD conversion circuit according to claim 6, wherein
the adjustment signal includes the first pulse amplitude and the second pulse amplitude at a time interval that is approximately a half of the first cycle.

8. The AD conversion circuit according to claim 5, further comprising
a decimation filter that is provided on output sides of the first delta-sigma conversion circuit and the second delta-sigma conversion circuit,
wherein the adjustment signal has a frequency falling in a frequency band that can be eliminated in the decimation filter.

9. The AD conversion circuit according to claim 1, wherein
the first delta-sigma conversion circuit further includes an integration circuit provided on the first signal line and including a switched capacitor for an input signal and a switched capacitor for a reference signal, and
the second delta-sigma conversion circuit further includes an integration circuit provided on the second signal line and including a switched capacitor for an input signal and a switched capacitor for a reference signal.

10. The AD conversion circuit according to claim 1, wherein
the first delta-sigma conversion circuit further includes
a first integration circuit that is provided on the first signal line,
a second integration circuit that is provided on the first signal line between the first integration circuit and the first quantizer, and
the intermediate node is a node on the first signal line between the first integration circuit and the second integration circuit.

11. The AD conversion circuit according to claim 10, wherein
the first signal line transmits an input signal, and
the adjustment circuit inputs an adjustment signal that is cyclic into the intermediate node of the first signal line.

12. The AD conversion circuit according to claim 10, wherein
the adjustment circuit includes a line electrically connecting an adjustment signal generation circuit to the intermediate node of the first signal line.

13. The AD conversion circuit according to claim 11, wherein
the adjustment signal has a frequency that is higher than a signal band.

14. The AD conversion circuit according to claim 13, wherein
the adjustment signal includes first pulse amplitude at a first cycle corresponding to the frequency that is higher than the signal band and second pulse amplitude at a second cycle corresponding to the frequency that is higher than the signal band.

15. The AD conversion circuit according to claim 14, wherein
the adjustment signal includes the first pulse amplitude and the second pulse amplitude at a time interval that is approximately a half of the first cycle.

16. The AD conversion circuit according to claim 13, further comprising
a decimation filter that is provided on output sides of the first delta-sigma conversion circuit and the second delta-sigma conversion circuit,
wherein the adjustment signal has a frequency falling in a frequency band that can be eliminated in the decimation filter.

17. The AD conversion circuit according to claim 10, wherein
the first integration circuit includes a switched capacitor for an input signal and a switched capacitor for a reference signal, and
the second integration circuit includes a switched capacitor for an input signal and a switched capacitor for a reference signal.

18. The AD conversion circuit according to claim 1, wherein
the first quantizer includes
an AD converter having 1.5-bit resolution, and
a DA converter having 1.5-bit resolution.

19. The AD conversion circuit according to claim 18, wherein
the AD converter is electrically connected between the first signal line and an output node of the first delta-sigma conversion circuit, and
the DA converter is electrically connected between the output node of the first delta-sigma conversion circuit and the first feedback line.

20. The AD conversion circuit according to claim 1, further comprising:
a decimation filter; and
an error reduction circuit that is electrically connected between the first delta-sigma conversion circuit and the second delta-sigma conversion circuit, and the decimation filter.
